(19) United States
(12) Patent Application Publication
(10) Pub. No.: US 2019/0327849 A1
(43) Pub. Date: Oct. 24, 2019

(54) Modular Size-Adjustable Processor Containment System

(71) Applicant: SUZHOU A-RACK ENCLOSURE SYSTEMS CO., LTD., Suzhou, Jiangsu (CN)

(72) Inventor: ZhiYong DING, Suzhou (CN)

(73) Assignee: Suzhou A-Rack Enclosure Systems Co., Ltd., Suzhou, Jiangsu (CN)

(21) Appl. No.: 15/860,119

(22) PCT Filed: Sep. 11, 2017
(86) PCT No.: PCT/CN2017/101279

§ 371 Date: Jul. 11, 2019

(30) Foreign Application Priority Data
Jun. 15, 2017 (CN) 2017104520094.X

(51) Int. Cl. H05K 7/14; A47B 47/00; H05K 5/02

(52) U.S. Cl. CPC H05K 7/1488; A47B 96/14; H05K 5/0226; A47B 47/0091

(57) ABSTRACT

A modular container comprises an integral rack, a side plate, a door plate and a top plate. The integral rack is formed by at least one rack. Each rack comprises at least three columns, an upper beam and a lower beam. The at least three columns are staggered in the horizontal direction and parallel in the vertical direction. Two ends of the upper beam are fixedly connected to top ends of two adjacent columns. The two ends of lower beam are fixedly connected to bottom ends of two adjacent columns. The side plate is between the upper beam and the lower beam located at the outer side of integral rack and opposite to each other. One side of the door plate is rotatably connected to the corresponding column located at the outer side of the integral rack. The top plate is located at the top end of integral rack.

### CROSS REFERENCE OF RELATED APPLICATIONS

This application claims the benefits of International application no. PCT/CN2017/101279, filed Sep. 11, 2017 and entitled MODULAR CONTAINER, which provisional application is incorporated by reference herein in its entirety.

### FIELD OF THE INVENTION

The present invention relates generally to a modular size-adjustable processor containment system for housing processers. More so, the present invention relates to a containment system that provides modular, size-adjustable containers that adapt to changing sizes, power, and configurations of processors being stored inside the container, such as processors used in a data center

### BACKGROUND OF THE INVENTION

The following background information may present examples of specific aspects of the prior art (e.g., without limitation, approaches, facts, or common wisdom) that, while expected to be helpful to further educate the reader as to additional aspects of the prior art, is not to be construed as limiting the present invention, or any embodiments thereof, to anything stated or implied therein or inferred thereupon.

Typically, containers configured to store computers and related control equipment are fabricated from cold-rolled steel or alloy. These containers provide protection for the stored equipment, shield electromagnetic interference, and arrange the equipment orderly and neatly, so as to facilitate follow-up maintenance of the equipment. The containers are generally classified into server containers, network containers, console containers, etc., and are widely applied to weak current machine rooms in the fields of electronic communications, power, aerospace, airports and the like.

It is known in the art that containers are manufactured according to the sizes of equipment needed to be placed therein, so that each produced container only has one specific size. Once the size of the computer or the related control equipment to be placed inside the container is changed, the size of the container will not match with that of the equipment to be placed therein. As a result, it is necessary to re-produce a container matched with the equipment in size, causing time waste. In addition, the original container cannot be reused, so that production materials are wasted

Other proposals have involved containers for storing processors, networks, and hardware. The problem with these containers is that they are only used for one type of processor configuration. Also, they do not allow for adaptability to adjust to changes in power, types, and configurations of processors. Even though the above cited containers meet some of the needs of the market, a modular size-adjustable processor containment system used for housing processers, such as processors, servers, networks, and consoles housed in a data center that enables the containers to be easily adaptable to changing sizes, power, and configurations of processors being stored inside the container is still desired.

### SUMMARY

Illustrative embodiments of the disclosure are generally directed to a modular size-adjustable processor containment system. The containment system provides modular, size-adjustable containers used for housing processers, such as processors, servers, networks, and consoles housed in a data center. The processor containment system enables the containers to be easily adaptable to changing sizes, power, and configurations of processors being stored inside the container. The containment system is configured to house various processors, known in the art of data centers or other processor-dependent sites known in the art.

In some embodiments, the processor containment system comprises an integral rack, a side plate, a door plate and a top plate. The integral rack is formed by at least one rack. Each rack comprises at least three columns, an upper beam and a lower beam, wherein the at least three columns are staggered in the horizontal direction and parallel in the vertical direction. The two ends of the upper beam are fixedly connected to the top ends of two adjacent columns, respectively.

The two ends of the lower beam are fixedly connected to the bottom ends of two adjacent columns, respectively. The side plate is arranged between the upper beam and the lower beam which are located at the outer side of the integral rack and opposite to each other. One side of the door plate is rotatably connected to the corresponding column located at the outer side of the integral rack. The top plate is located at the top end of the integral rack.

In one non-limiting embodiment, the present disclosure provides a modular container whose size can be changed fast. In some embodiments, the present disclosure may adopt the following technical solutions: A modular container, comprises: an integral rack, a side plate, a door plate and a top plate.

Further, the integral rack may be formed by at least one rack, wherein each rack comprises: at least three columns staggered in the horizontal direction and parallel in the vertical direction; an upper beam whose two ends are fixedly connected to the top ends of two adjacent columns, respectively; and a lower beam whose two ends are fixedly connected with the bottom ends of the two adjacent columns, respectively.

Further, the side plate may be arranged between the upper beam and the lower beam which are located at the outer side of the integral rack and opposite to each other; one side of the door plate is rotatably connected to the column located at the outer side of the integral rack; and the top plate is located at the top end of the integral rack.

Optionally, the integral rack is spliced by at least two racks, and two abutting columns of the at least two racks are fixedly connected.

Optionally, the rack comprises: four columns, a rectangular frame spliced by four upper beams, and a rectangular frame spliced by four lower beams, wherein the upper beams and the lower beams are fixedly connected with the columns via bolts, respectively.

Optionally, the column is made by bending a sheet metal, and comprises two L-shaped folded plates; and the upper beam and the lower beam are respectively accommodated at the upper end and the lower end of a space formed by the L-shaped folded plates, and are fixedly connected with the upper ends and the lower ends of the L-shaped folded plates, respectively.

Optionally, the L-shaped folded plate comprises a first folded plate perpendicular to and connected with a second folded plate. The side of the second folded plate away from the first folded plate is a free end. The first upper side surface and the second upper side surface of the upper beam are perpendicular to each other; the first upper side surface is abutted against the second folded plate; and the second upper side surface is abutted against the first folded plate.

Optionally, the first lower side surface and the second lower side surface of the lower beam are perpendicular to each other; the first lower side surface is abutted against the second folded plate; and the second lower side surface is abutted against the first folded plate. The second folded plate and the first upper side surface are fixedly connected via bolts; and the second folded plate and the first lower side surface are fixedly connected via bolts.

Optionally, there are multiple racks. The second folded plates on two abutting columns of different racks form an accommodating cavity in which a connecting block is provided; the two second folded plates are connected with the connecting block via bolts.

Optionally, the upper beam is provided with an upper connecting plate; and the lower beam is provided with a lower connecting plate. The side plate is accommodated in a space formed by the columns, the upper beam and the lower beam, and is fixedly connected with the first folded plate, the upper connecting plate and the lower connecting plate via bolts, respectively.

Optionally, the door plate and the columns are hinged via hinges; and one side of the hinge is detachably mounted on the corresponding column.

Optionally, a supporting rod is fixedly arranged between the upper beam and the lower beam which are opposite to each other.

Optionally, a supporting frame is fixedly arranged inside the rack. The modular container provided by the present disclosure comprises an integral rack formed by at least one rack. Each rack comprises at least three columns staggered in the horizontal direction and parallel in the vertical direction, the upper beam and the lower beam. When equipment to be placed is small in size, the side plate, the door plate and the top plate are mounted on one rack to assemble a small-sized container for use.

Optionally, when equipment to be placed is large in size, the multiple racks are spliced according to the size of the equipment to form the integral rack whose internal volume is matched with the size of the equipment, and then the side plates and the door plates are mounted at the outer side of the integral rack to assemble a modular container whose internal volume is matched with the size of the equipment.

Further, the modular container provided by the present disclosure is flexible in disassembling and assembling, and can change the size thereof fast according to different sizes of the equipment, so that lots of time and labor are saved; and the waste of production materials is avoided as the single rack may be repeatedly used.

One objective of the present invention is to adapt a container to receive and house various types, sizes, and powers of processors through easy arrangement of plates, racks, and columns in the container.

Another objective is to enable expedited changing of the dimensions of the container.

Yet another objective is to provide an inexpensive to manufacture processor container, as used in data centers.

Yet another objective is to reduce the waste of production materials, as the single rack may be repeatedly used.

Yet another objective is to make data centers more profitable by reducing the need to purchase new containers when the processor needs change.

Other systems, devices, methods, features, and advantages will be or become apparent to one with skill in the art upon examination of the following drawings and detailed description. It is intended that all such additional systems, methods, features, and advantages be included within this description, be within the scope of the present disclosure, and be protected by the accompanying claims and drawings.

### BRIEF DESCRIPTION OF THE DRAWINGS

The invention will now be described, by way of example, with reference to the accompanying drawings, in which:

FIG. 1 is a schematically structural view of an exemplary modular size-adjustable processor containment system comprising a single rack, in accordance with an embodiment of the present disclosure;

FIG. 2 is a partial enlarged view of part A in FIG. 1, in accordance with an embodiment of the present disclosure;

FIG. 3 is an exploded view of the processor containment system comprising the single rack, in accordance with an embodiment of the present disclosure;

FIG. 4 is a schematically structural view of a modular container comprising a plurality of racks, in accordance with an embodiment of the present disclosure;

FIG. 5 is an exploded view of the modular container comprising the plurality of racks, in accordance with an embodiment of the present disclosure;

FIG. 6 is a schematically structural view of a single rack mounted with a supporting frame, in accordance with an embodiment of the present disclosure;

FIG. 7 is a partial enlarged view of part B in FIG. 6, in accordance with an embodiment of the present disclosure;

FIG. 8 is a schematically structural view of a single rack, in accordance with an embodiment of the present disclosure;

FIG. 9 is a partial enlarged view of part C in FIG. 8, in accordance with an embodiment of the present disclosure;

FIG. 10 is a schematically structural view of a column, in accordance with an embodiment of the present disclosure;

FIG. 11 is a first schematic view of an upper beam, in accordance with an embodiment of the present disclosure;

FIG. 12 is a second schematic view of the upper beam, in accordance with an embodiment of the present disclosure;

FIG. 13 is a first schematic view of a lower beam, in accordance with an embodiment of the present disclosure;

FIG. 14 is a second schematic view of the lower beam, in accordance with an embodiment of the present disclosure; and

FIG. 15 is a schematically structural view of another lower beam, in accordance with an embodiment of the present disclosure.

Like reference numerals refer to like parts throughout the various views of the drawings.

### DETAILED DESCRIPTION OF THE INVENTION

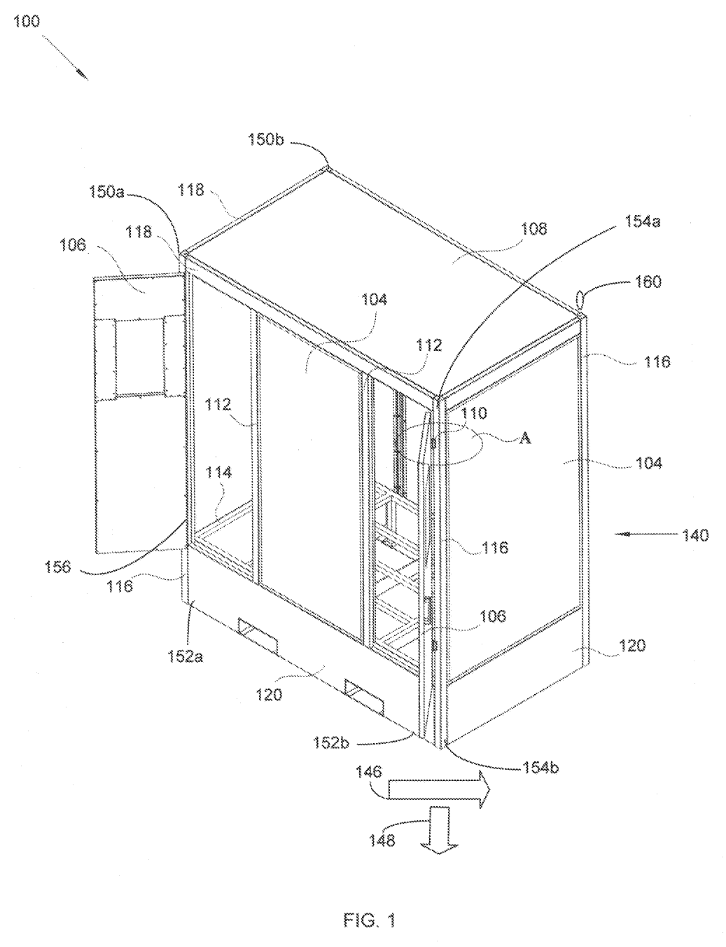

The following detailed description is merely exemplary in nature and is not intended to limit the described embodiments or the application and uses of the described embodiments. As used herein, the word “exemplary” or “illustrative” means “serving as an example, instance, or illustration.” Any implementation described herein as “exemplary” or “illustrative” is not necessarily to be construed as preferred or advantageous over other implementations. All of the implementations described below are exemplary implementations provided to enable persons skilled in the art to make or use the embodiments of the disclosure and are not intended to limit the scope of the disclosure, which is defined by the claims. For purposes of description herein, the terms “upper,” “lower,” “left,” “rear,” “right,” “front,” “vertical,” “horizontal,” and derivatives thereof shall relate to the invention as oriented in FIG. 1. Furthermore, there is no intention to be bound by any expressed or implied theory presented in the preceding technical field, background, brief summary or the following detailed description. It is also to be understood that the specific devices and processes illustrated in the attached drawings, and described in the following specification, are simply exemplary embodiments of the inventive concepts defined in the appended claims. Specific dimensions and other physical characteristics relating to the embodiments disclosed herein are therefore not to be considered as limiting, unless the claims expressly state otherwise.

A modular size-adjustable processor containment system 100 is referenced in FIGS. 1-15. As referenced in FIG. 1, the modular size-adjustable processor containment system 100, hereafter “system 100”, provides modular, size-adjustable containers 140 used for housing processers, such as processors, servers, networks, and consoles housed in a data center. The system 100 enables the containers 140 to be easily adaptable to changing sizes, power, and configurations of processors being stored inside the container. The container 140 is configured to house various processors, known in the art of data centers or other processor-dependent sites known in the art.

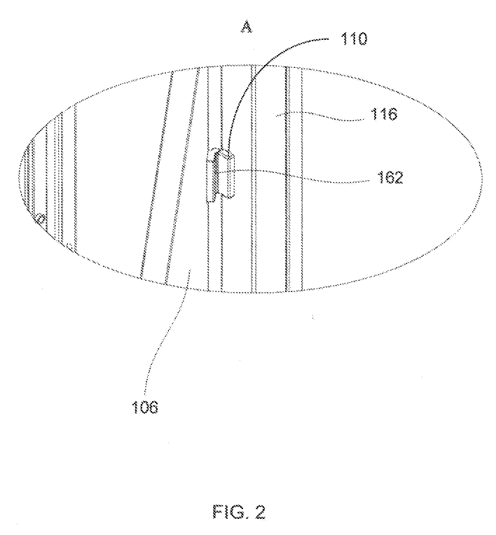

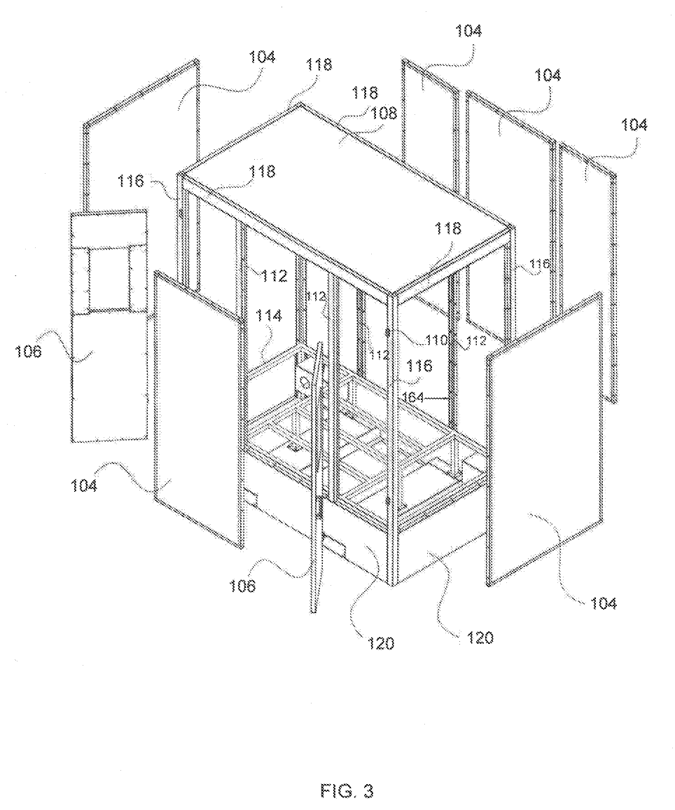

As shown in FIG. 2, embodiments of the present disclosure the system 100 provides a modular container 140 comprising an integral rack 142, side plates 104, door plates 106, and a top plate 108. The integral rack 142 is formed by at least one rack 102. Each rack 102 comprises at least three columns 116, an upper beam 118 and a lower beam 120, wherein the at least three columns 116 are staggered in a horizontal direction 146 and parallel in a vertical direction 148. FIG. 3 is an exploded view of the processor containment system comprising the single rack.

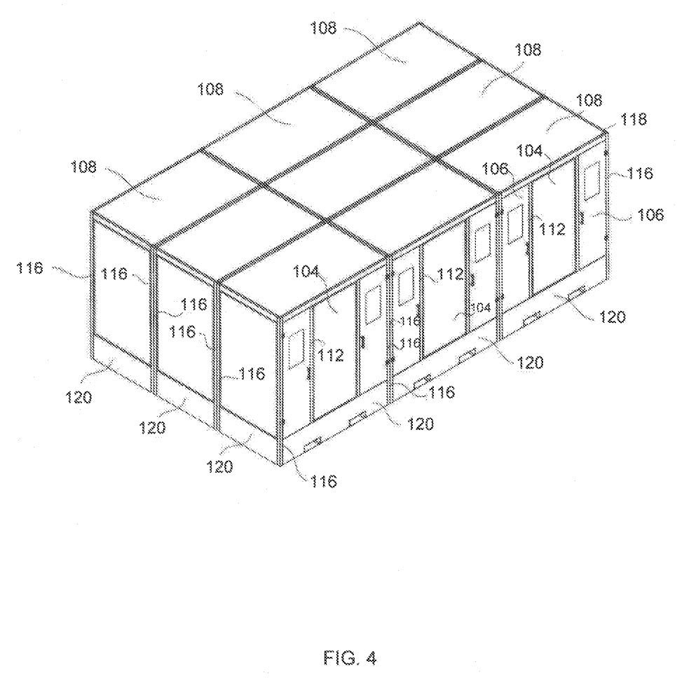

Looking now at FIG. 4, the upper beam 118 is defined by two ends 150a, 150b. The two ends 150a-b of the upper beam 118 are fixedly connected to top ends 154a of two adjacent columns 116, respectively. The lower beam 120 is defined by two ends 152a, 152b. The two ends 152a-b of the lower beam 120 are fixedly connected to the bottom ends 154b of two adjacent columns 116, respectively.

As FIG. 5 references, the side plates 104 are arranged between the upper beam 118 and the lower beam 120 which are located at an outer side 144 of the integral rack 142 and opposite to each other. One side 156 of each door plate 106 is rotatably connected to the corresponding column 116 located at the outer side 144 of the integral rack 142. The top plate 108 is located at a top end 158 of the integral rack 142.

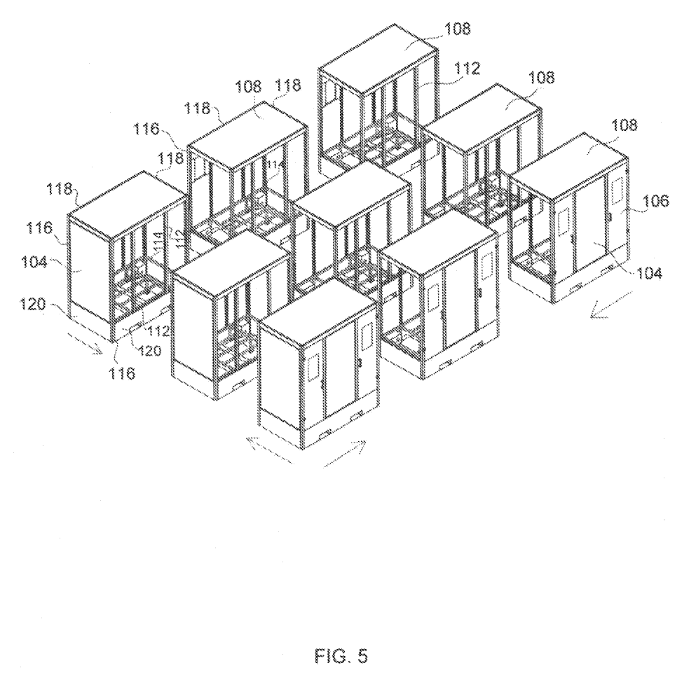

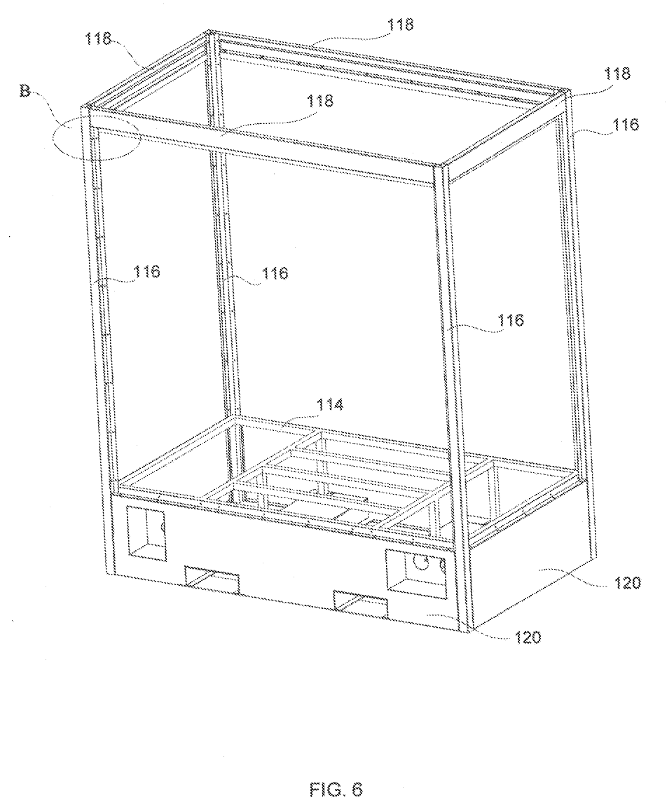

In another embodiment shown in FIG. 6, the system 100 may include one rack 102 that is joined in the modular container 140. The modular container 140 may include side plates 104, door plates 106, and a top plate 108, wherein the side plates 104 are arranged between the upper beam 118 and the lower beam 120 which are opposite to each other; one side of each door plate 106 is rotatably connected to the corresponding column 116; and the top plate 108 is located at the top end of the upper beam 128.

When the equipment to be placed in the container is small, only the single rack 102 is required to form a small modular container. When the equipment to be placed in the container 140 is large, multiple racks are spliced according to the size of the equipment to form the integral rack; and the side plates 104 and the door plates 106 are mounted on the integral rack 142 to form the modular container 140 whose internal volume is matched with the size of the equipment.

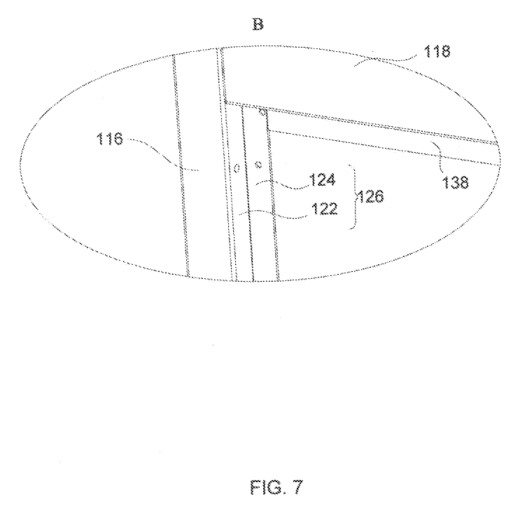

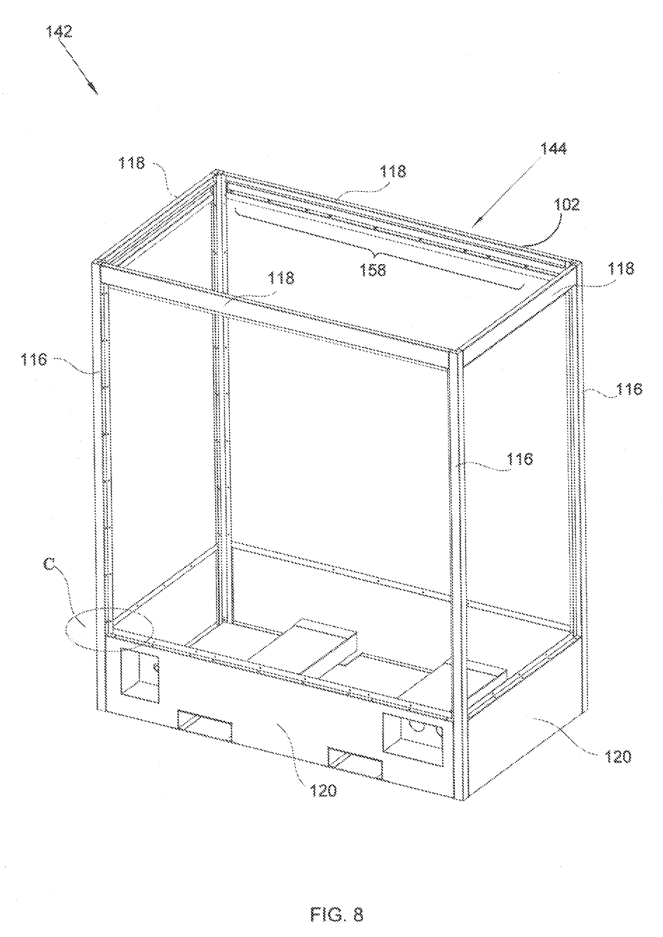

As shown in FIG. 7, the modular container 140 provided by this embodiment is flexible in disassembling and assembling; and different sizes of modular containers can be obtained fast in accordance with different sizes of the equipment, so that lots of time and labor are saved; and the waste of production materials is avoided as the single rack 102 may be repeatedly used. In addition, the multiple racks 102 may be welded after being spliced so as to be fixed, and the produced modular container 140 may be used indoors or outdoors (FIG. 8).

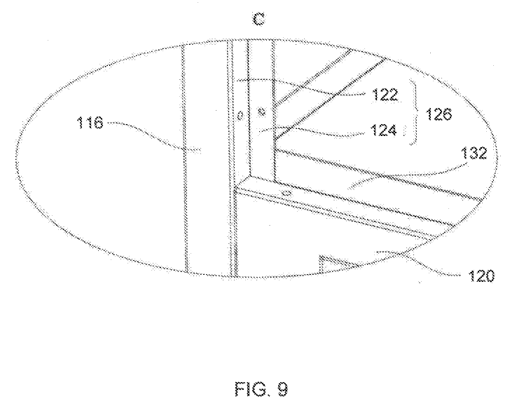

Optionally, as FIG. 9 show, the rack 102 in this embodiment comprises four columns 116, a rectangular frame spliced by four upper beams 118 and a rectangular frame spliced by four lower beams 120; and the areas enclosed by the two rectangular frames are the same. The two rectangular frames and the four columns 116 form the cuboid rack, which facilitates the splicing of the plurality of racks. When the integral rack 142 is spliced by at least two racks, two abutting columns 116 of different racks are fixedly connected, so that the integral rack is more stable and has a better supporting effect.

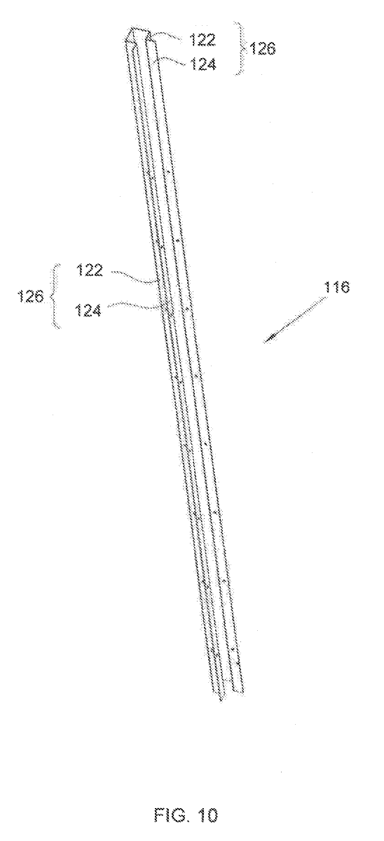

As referenced in FIG. 10, the upper beam 118 and the lower beam 120 are respectively fixedly connected with the columns 116 via bolts 160. Optionally, the column 116 is made by bending a sheet metal, and comprises two L-shaped folded plates 126. The L-shaped folded plate 126 is also known as a right-angle bending folded plate. The upper beam 118 and the lower beam 120 are respectively accommodated at the upper end and the lower end of a space formed by the L-shaped folded plates 126, and are fixedly connected with the upper ends and the lower ends of the L-shaped folded plates 126, respectively.

Further, the L-shaped folded plate 126 comprises a first folded plate 122 perpendicular to and connected with a second folded plate 124. The side of the second folded plate 124 away from the first folded plate 122 is a free end. The first upper side surface 134 and the second upper side surface 136 of the upper beam 118 are perpendicular to each other; the first upper side surface 134 is abutted against the second folded plate 124; and the second upper side surface 136 is abutted against the first folded plate 122 (FIG. 11).

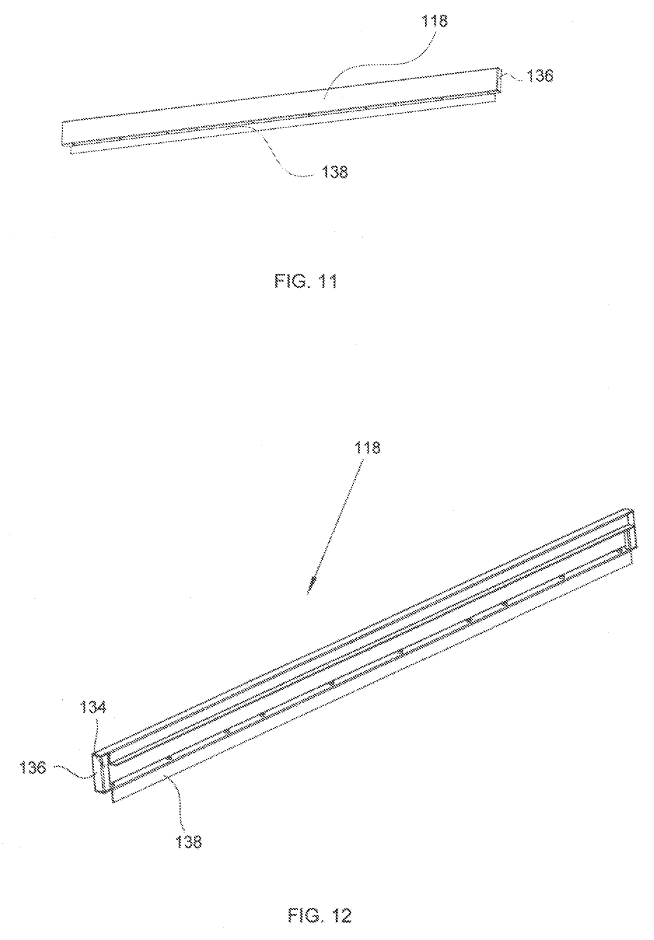

The first lower side surface 128 and the second lower side surface 132 of the lower beam 120 are perpendicular to each other (FIG. 12). The first lower side surface 128 is abutted against the second folded plate 124; and the second lower side surface 132 is abutted against the first folded plate 122. The second folded plate 124 and the first upper side surface 134 are fixedly connected via bolts 160; and the second folded plate 124 and the first lower side surface 128 are fixedly connected via bolts 160.

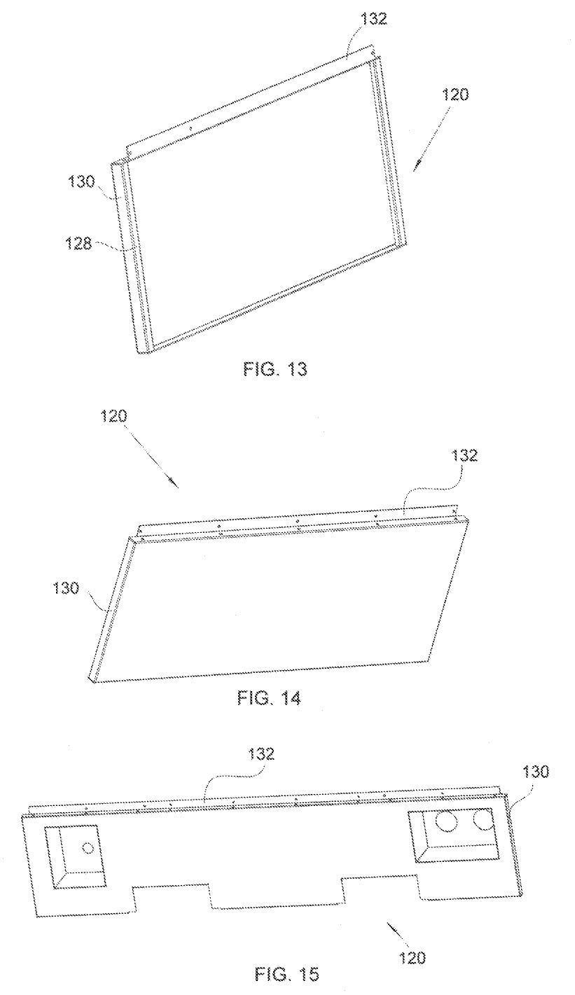

Thus, by arranging the first folded plate 122 and the second folded plate 124, it is possible to ensure that the side surfaces of the upper beam 118 and the lower beam 120 are closely abutted against the L-shaped folded plates 126, respectively. (FIGS. 13, 14, 15), so that contact areas of the upper beam 118 and the lower beam 120 with the corresponding L-shaped folded plates 126 are increased, respectively, and bolt fixing is more firm.

In this embodiment, when there are multiple racks 102, the second folded plates 124 on two abutting columns 116 of different racks 102 form an accommodating cavity in which a connecting block is provided; and the two second folded plates 124 are fixedly connected with the connecting block via bolts, so as to realize splicing and fixing of the plurality of different racks 102.

In this embodiment, shown back in FIG. 7, the upper beam 118 is provided with an upper connecting plate 138; the lower beam 120 is provided with a lower connecting plate 130; and the side plates 104 are accommodated in a space formed by the columns 116, the upper beam 118 and the lower beam 120, and are fixedly connected to the first folded plate 122, the upper connecting plate 138 and the lower connecting plate 130 via bolts, respectively. By arranging the first folded plate 122, the upper connecting plate 138 and the lower connecting plate 130, the contact areas between the side plates 104 and the columns 116, the upper beam 118 and the lower beam 120 can be increased, respectively, so that the side plates 104 are more firmly fixed to the columns 116, the upper beam 118 and the lower beam 120.

The door plates 106 and the columns 116 are hinged via hinges 110. One side 164 of the hinge 110 is detachably mounted on the corresponding column 116 (FIG. 2). When there is one rack 102, one side of the rack where the hinge 110 is directly mounted is connected to the corresponding column 116, and the other side thereof is connected with the corresponding door plate 106.

Thus, when multiple racks 102 are spliced into an integral rack, hinges 110 are mounted on the columns 116 of the integral rack where the door plates 106 required to be mounted at the outer side; and the side of the hinge 110 away from the column 116 is fixedly connected to one side of the corresponding door plate 106. Through the hinges 110, the rotation of the door plates 106 relative to the columns 116 is realized, so as to open or close the door plates.

According to the modular box body in this embodiment, supporting rods 112 are fixedly arranged between the upper beam 118 and the lower beam 120 which are opposite to each other to support the same so as to effectively enhance the strength of the modular container. In addition, a supporting frame 114 is fixedly arranged inside 164 the rack 102. The supporting frame 114 being configured to enhance the overall strength of the modular container 140, and support equipment.

The system 100 provides numerous industrial applications. For example, the modular container 140 is sufficiently flexible in disassembling and assembling, and can change the size thereof fast according to different sizes of equipment, so that time and labor is reduced. Further, waste of production materials is avoided as the single rack 102 may be used repeatedly.

These and other advantages of the invention will be further understood and appreciated by those skilled in the art by reference to the following written specification, claims and appended drawings.

Because many modifications, variations, and changes in detail can be made to the described preferred embodiments of the invention, it is intended that all matters in the foregoing description and shown in the accompanying drawings be interpreted as illustrative and not in a limiting sense. Thus, the scope of the invention should be determined by the appended claims and their legal equivalence.

What is claimed is:

1-20. (canceled)

21. A modular container, comprising: an integral rack, a side plate, a door plate and a top plate, wherein the integral rack is formed by at least one rack; the rack comprises at least three columns staggered in the horizontal direction and parallel in the vertical direction, an upper beam whose two ends are fixedly connected to the top ends of two adjacent columns, respectively, and
a lower beam having two ends being fixedly connected with the bottom ends of the two adjacent columns, respectively; and
the side plate is arranged between the upper beam and the lower beam, wherein the upper beam and the lower beam are located at the outer side of the integral rack and opposite to each other, wherein one side of the door plate is rotatably connected to the column located at the outer side of the integral rack, and the top plate is located at the top end of the integral rack.

22. The modular container according to claim 21, wherein the integral rack is spliced by at least two racks, and two abutting columns of the at least two racks are fixedly connected.

23. The modular container according to claim 22, wherein the rack comprises four columns, a rectangular frame spliced by four upper beams, and a rectangular frame spliced by four lower beams; and the upper beams and the lower beams (13) are fixedly connected with the columns via bolts, respectively.

24. The modular container according to claim 23, wherein the column is made by bending a sheet metal, and comprises two L-shaped folded plates; and the upper beam and the lower beam are respectively accommodated at the upper end and the lower end of a space formed by the L-shaped folded plates, and are fixedly connected with the upper ends and the lower ends of the L-shaped folded plates, respectively.

25. The modular container according to claim 24, wherein the L-shaped folded plate comprises a first folded plate perpendicular to and connected with a second folded plate; wherein the side of the second folded plate away from the first folded plate is a free end; wherein the first upper side surface and the second upper side surface of the upper beam are perpendicular to each other; wherein the first upper side surface is abutted against the second folded plate; wherein the second upper side surface is abutted against the first folded plate; the first lower side surface and the second lower side surface of the lower beam are perpendicular to each other; wherein the first lower side surface is abutted against the second folded plate; wherein the second lower side surface is abutted against the first folded plate; wherein the second folded plate and the first upper side surface are fixedly connected via bolts; and the second folded plate and the first lower side surface are fixedly connected via bolts.

26. The modular container according to claim 25, further comprising multiple racks, the second folded plates on two abutting columns of different racks form an accommodating cavity in which a connecting block is provided, the two second folded plates are fixedly connected with the connecting block via bolts.

27. The modular container according to claim 26, wherein the upper beam is provided with an upper connecting plate, wherein the lower beam is provided with a lower connecting plate, wherein the side plate is accommodated in a space formed by the columns, wherein each of the upper beam and the lower beam is fixedly connected with the first folded plate, the upper connecting plate and the lower connecting plate via bolts, respectively.

28. The modular container according to claim 26, wherein the door plate and the columns are hinged via hinges, and one side the hinge is detachably mounted on the corresponding column.

29. The modular container according to claim 26, wherein a supporting rod is fixedly arranged between the upper beam and the lower beam, wherein the upper beam and the lower beam are opposite to each other.

30. The modular container according to claim 6, wherein a supporting frame is fixedly arranged inside the rack.
